(19) United States
(12) Patent Application Publication
(10) Pub. No.: US 2007/0158827 A1
(43) Pub. Date: Jul. 12, 2007

(54) Electronic device comprising at least one printed circuit board and comprising a plurality of semiconductor components of identical type, and method

(76) Inventor: Josef Schuster, Muenchen (DE)

Correspondence Address: SLATER & MATSIL LLP, 17950 PRESTON ROAD, SUITE 1000, DALLAS, TX, 75252, US

(21) Appl. No.: 11/640,465

(22) Filed: Dec. 15, 2006

(30) Foreign Application Priority Data
Dec. 15, 2005 (DE) 10 2005 060 081.6

(51) Int. Cl. H01L 23/34

(52) U.S. Cl. 257/723

(57) ABSTRACT

An electronic device is provided, in which semiconductor components are structurally identical among one another and have two groups of contact connections arranged on opposite main areas on a printed circuit board. Components are arranged in a manner laterally offset in a direction parallel to the printed circuit board area in such a way that, on opposite main areas, a group of first contact connections of a semiconductor component fitted on one main area is in each case arranged in the same region of the printed circuit board as a group of first contact connections of a semiconductor chip arranged on the opposite main area. Likewise, the groups of second contact connections of the semiconductor chips arranged on opposite main areas in each case attain congruence.

This application claims priority to German Patent Application 10 2005 060 081.6, which was filed Dec. 15, 2005, and is incorporated herein by reference.

### TECHNICAL FIELD

The invention relates to an electronic device comprising at least one printed circuit board and comprising a plurality of semiconductor components of mutually identical type. The invention furthermore relates to a method for producing such an electronic device.

### BACKGROUND

Electronic devices, for example memory modules, but also memory units of mobile and other devices, have a plurality of semiconductor components of identical type which in each case have an integrated semiconductor chip and are arranged jointly on an electronic printed circuit board. The electronic printed circuit board may, as in the case of a memory module, be able to be plugged into a main circuit board, for instance into a motherboard, or itself serve as a main circuit board. In the case of a memory module, the printed circuit board has a contact strip in order to connect it to a printed circuit board of a superordinate electronic unit. The main circuit boards of motherboards, but also of computers exhibiting higher level organization, usually have a multiplicity of connection strips, into each of which a memory module can be plugged.

In all these applications, the problem always arises of arranging a largest possible number of semiconductor components in densely packed fashion on the respective electronic printed circuit board in order to achieve the highest possible storage capacity with the smallest possible printed circuit board area. The storage capacity is influenced not only by the storage capacity (that is to say the number of data bits that can be stored) of the individual semiconductor components, but also by the number of semiconductor components carried by a printed circuit board. Nowadays, the printed circuit boards, for example those of memory modules, are usually populated with semiconductor components on both sides. Furthermore, instead of only one semiconductor component, a plurality of semiconductor components stacked one above another can be arranged at each position of the printed circuit board in order, for example, once again to double or quadruple the storage capacity. The semiconductor components are usually BGAs (Ball Grid Arrays) having on their underside a multiplicity of contact connections arranged in two groups on both sides of a cutout. The contact connections produce the electrical connection on the printed circuit board side; they constitute two arrays of relatively densely packed soldering contacts. The chip-side contact connections, for instance bonding connections, may be provided in the region of the cutout between both groups of contact connections. The electrical connection to the integrated semiconductor chip contained in the semiconductor component is produced thereby.

In addition to the requirement for the highest possible packing density of the semiconductor components on the electronic printed circuit board there is furthermore the requirement for optimization and compatibility of the driving of the semiconductor components by the printed circuit board at high frequencies. At clock frequencies of above 400 megahertz, especially above 800 megahertz, there are considerable limitations with regards to the capacitive load reactances if a plurality of semiconductor components are driven in parallel with one another and their contact connections are connected in parallel with one another. However, with regard to the conductor track lengths, too, there is a demand for optimization in order to give rise, as far as possible, to no propagation time differences between semiconductor chips that are driven in parallel with one another.

In view of these requirements, it has proved worthwhile to populate the front side and the rear side of a printed circuit board of an electronic device with semiconductor components arranged in an identical manner, since the front-side and rear-side printed circuit board areas are identical in size and the arrangement of the semiconductor components that has in each case found to be optimum when used on both sides of the printed circuit board. Thus, although there are many different component arrangements which can be varied depending on the lateral dimensions of the semiconductor components themselves and the printed circuit board, what is common to them is that, at least when the semiconductor components are packed very densely alongside one another on the printed circuit board in order to utilize the printed circuit board area as well as possible under the given circumstances, the lateral arrangement of the semiconductor components is the same on the front side and rear side of the printed circuit board. This simultaneously predefines the arrangement of further semiconductor components which can be stacked on the semiconductor components mounted directly at the printed circuit board.

Electronic printed circuit boards are nowadays produced as multilayer printed circuit boards which have, besides the outer conductor track planes on both outer sides, one or more inner conductor track planes which are isolated from one another by insulation planes. Contact hole fillings within said insulation planes produce local connections between the lines which run in the conductor track planes. A technique known as fly by technology provides for the memory components arranged on the front side and the rear side of the printed circuit board to be driven by the same conductor tracks, that is to say by the same line bus. The line bus comprises lines which are connected to contact hole fillings only in the region of the base areas of the semiconductor chips fitted on both sides, which contact hole fillings, proceeding from said lines, produce a relatively short connection to the respective semiconductor component, if appropriate with the aid of further, shorter conductive structures in or between the conductor track planes. This obviates the need to lead longer line segments proceeding from a branching node to the respective semiconductor components; such branched line segments would run in a lateral direction parallel to the printed circuit board area. The lines of the common line bus of the semiconductor components driven by fly by technology can be led through, between the semiconductor components, in a central conductor track plane of the printed circuit board. By means of such a line bus, semiconductor components arranged on both sides alongside one another on the printed circuit board are electrically driven in parallel with one another. By means of fly by technology, the conductor track courses for the front-side and rear-side semiconductor components can be led through the printed circuit board in a similar manner since the semiconductor components have the same positions on both sides of the printed circuit board. This in turn makes it possible to adhere to the conventional principle of arranging the memory components on both sides of the printed circuit boards in the same positions within the printed circuit board area for space reasons and for reasons of storage capacity.

### SUMMARY OF THE INVENTION

In one aspect the present invention provides a novel electronic device which has a high packing density of the semiconductor components on a printed circuit board and thus a high storage capacity and which additionally affords the possibility of reliably driving the semiconductor components at even higher clock frequencies than are conventionally possible. In particular, the object of the invention is to provide an electronic device in which the electrical interconnection of the memory components within the printed circuit board is simplified and in which the conductor track paths that lead to the individual contact connections of the semiconductor components are as short as possible. In particular, the object of the present invention is to provide an electronic device which has, for semiconductor components whose electrical contact connections are arranged in two arrays of contact connections that are isolated from one another, an even more extensively optimized electrical interconnection than conventional electronic devices.

The invention includes an electronic device comprising at least one printed circuit board and comprising a plurality of semiconductor components of mutually identical type,
the printed circuit board having a first main surface and a second main surface remote from the first main surface, which extend along a first and a second direction,
the plurality of semiconductor components comprising first semiconductor components arranged on the first main surface of the printed circuit board, and second semiconductor components arranged on the second main surface of the printed circuit board,
each semiconductor component having an outer surface which faces the printed circuit board and extends from a first edge of the semiconductor component as far as an opposite second edge of the semiconductor component,
each semiconductor component having contact connections which are provided in the region of its outer surface and are arranged in two groups of contact connections on the outer surface,
a group of first contact connections in each case being arranged in a region of the outer surface of the respective semiconductor component which is arranged nearer to the first edge of the semiconductor component, and a group of second contact connections in each case being arranged in a region of the outer surface of the respective semiconductor component which is arranged nearer to the second edge of the semiconductor component,
the semiconductor components being arranged in oriented fashion on the printed circuit board such that the first and the second edge of the semiconductor components run parallel to the second direction, and that the first edge of the second semiconductor components points in the opposite direction to the first edge of the first semiconductor components, and
the semiconductor components of the plurality of semiconductor components being lined up in a manner offset with respect to one another along the first direction such that, with respect to the first direction centrally between in each case two first semiconductor components which are arranged adjacent to one another on the first main surface of the printed circuit board, a second semiconductor component is in each case arranged on the second main surface of the printed circuit board, the base area of said semiconductor component on the printed circuit board in each case overlapping the base areas of the respective first semiconductor components on the printed circuit board in regions along the first direction,
in a lateral direction, in each case the group of the first contact connections of the second semiconductor component attaining congruence with the group of the first contact connections of one first semiconductor component and the group of the second contact connections of the second semiconductor component attaining congruence with the group of the second contact connections of the other first semiconductor component.

In one embodiment, the invention is based on semiconductor components, for instance on packaged semiconductor chips, which have an outer surface extending between a first edge and an opposite second edge. Both edges run parallel to one another and point in the respectively opposite direction away from the chip of the semiconductor component. If the semiconductor component is mounted on the printed circuit board with its outer surface facing said printed circuit board, both edges run, for example, parallel to a second lateral direction along which the printed circuit board area extends, but point (with their area normals) in a first direction (along which the printed circuit board area likewise extends) but with a different directional sense. Thus, by way of example, the first edge of a semiconductor component may point in the positive x direction, while the second edge points in the negative x direction.

Embodiments of the invention are furthermore based on the fact that the semiconductor components considered here are all of mutually identical type. A distinction between first and second semiconductor components is made below with regard to whether the respective semiconductor component is arranged on the front side or the rear side of the printed circuit board. Said semiconductor components are structurally identical among one another, but arranged differently. The semiconductor components have a group of first contact connections arranged nearer to the first edge of the respective semiconductor component than to the second edge thereof. The components, furthermore, have a group of second contact connections arranged nearer to the second edge than to the first edge of the semiconductor component. A cutout for chip-side contact-making may be provided between the first and second groups of contact connections. The semiconductor components are ball grid arrays (BGA), by way of example.

According to embodiments of the invention, the semiconductor components are arranged in oriented fashion on the printed circuit board such that the first and the second edge of the semiconductor components run parallel to the second direction and the first edge of the second semiconductor components point in the opposite direction to the first edge of the first semiconductor components. Consequently, on each printed circuit board area, the orientation of the semiconductor components arranged thereon is uniform. However, the rear-side semiconductor components are arranged in a manner mirror-reflected by 180 degrees with respect to the front-side semiconductor components. This means that when the front-side semiconductor components point with the area normal of the first edge (i.e., the first edge area) in the positive x direction, the first edges of the rear-side semiconductor components point in the negative x direction, to be precise as viewed from the front side of the printed circuit board, that is to say from the same direction as in the case of a plan view of the front side of the printed circuit board. Consequently, the first edge of the first, front-side semiconductor components and the first edge of the second, rear-side semiconductor components point in mutually opposite directions. Consequently, the first edges of the semiconductor components on the front side and the second edges of the semiconductor components on the rear side of the printed circuit board face the positive x direction. The direction of an edge is predefined by the area normal—pointing to the exterior of the semiconductor component—of a corresponding edge area or of a corresponding region at the edge of the semiconductor component.

According to embodiments of the invention, the semiconductor components oriented in this way are lined up in a manner offset with respect to one another along the first direction such that, along the first direction between, in each case, two semiconductor components which are arranged adjacent to one another on the first main surface of the printed circuit board, a second semiconductor component is in each case arranged on the printed circuit board, the base area of said semiconductor component on the second main surface of the printed circuit board in each case overlapping the base areas of the respective first semiconductor components on the printed circuit board in regions along the first direction. The two main areas of the printed circuit board are the front side and the rear side of the printed circuit board, or vice versa. The base areas of the front-side and rear-side semiconductor chips are offset relative to one another along the first direction, to be precise only to an extent such that the base areas of the front-side semiconductor components and the base areas of the rear-side semiconductor components partly overlap one another. The base areas of the rear-side semiconductor components thus also bridge the interspace between two respective front-side semiconductor components along the first direction x. Consequently, a second, rear-side semiconductor component is arranged between in each case two first, front-side semiconductor components.

According to embodiments of the invention, it is furthermore provided that the first and second semiconductor components lined up in the first direction are offset with respect to one another such that, in the first direction, in each case the group of the first contact connections of a second semiconductor component attains congruence with the group of the first contact connections of one first semiconductor component and the group of the second connections of the second semiconductor component likewise attains congruence with the group of the second contact connections of the other first semiconductor component. Consequently, the front-side and rear-side semiconductor components are arranged offset with respect to one another such that their groups of first and second contact connections, of which in each case one group is present on each (first or second), semiconductor component, are in each case arranged at the same lateral positions as on the opposite side of the printed circuit board. Consequently, the group of first contact connections of a (second) semiconductor component mounted on the rear side is arranged laterally along the rear-side printed circuit board area at the same or approximately the same position as the corresponding group of first contact connections of one of the two first semiconductor chips, the base area of which partly overlaps that of the rear-side second semiconductor component and which are arranged on the front-side printed circuit board area. In the case of the other of the first front-side semiconductor components, the base area of this semiconductor component overlapping that of the rear-side second semiconductor component in regions, the position of its group of second contact connections along the printed circuit board area is identical to that of the group of second contact connections of the rear-side second semiconductor component. If this connection principle is applied to a series of a plurality of semiconductor components, this gives rise to a sequence of semiconductor components arranged relative to one another, in each case, in a manner laterally offset with respect to one another, the lined-up semiconductor components being arranged on both sides of the printed circuit board alternately in a manner offset in each case by a segment in the direction of for instance a (positive) first direction. Apart from at most one group of contact connections of a first and of a last semiconductor component of this lining-up of semiconductor components, all of the groups of contact connections of the semiconductor components are arranged at the same positions as on the respective opposite printed circuit board side. This enables the shortest possible connecting paths between the groups of connection contacts on the front side and rear side. In particular, in the region of the lining-up of semiconductor chips, the front-side and the rear-side semiconductor components can be driven by the shortest possible line paths whose branching nodes are essentially arranged at the same lateral positions as the contact connections of the semiconductor components themselves. As a result, from conductor tracks which run in an inner conductor track plane of the printed circuit board, toward the top side and toward the rear side of the printed circuit board electrical connections can in each case be led through the remaining planes of the printed circuit board without appreciable lateral line paths, that is to say line paths running parallel to the printed circuit board main area, being required. The construction of the electronic device according to the invention is compatible with conventional fly by technology, and, moreover, despite or precisely because of the laterally offset arrangement of the front-side and rear-side semiconductor components, leads to a shortening of the required conductor track lengths for driving the respective front-side and rear-side semiconductor components. In comparison with the component arrangements that are conventionally chosen for space reasons and in the case of which the lateral positions of the semiconductor components on the front side and rear side of the printed circuit board are identical (apart from the orientation of the semiconductor components themselves), the offset arrangement according to the invention of the front-side and rear-side semiconductor components along one or more rows along a predefined direction enables the electronic device overall to be operated at even higher clock frequencies than conventional electronic devices owing to the branching lines that can be configured even shorter according to the invention.

Preferably, the second semiconductor components arranged on the rear side are arranged centrally between two respective first semiconductor components on the front side. Particularly in the case of the usually symmetrically arranged two groups of contact connections of each semiconductor component, the respective groups of contact connections can be arranged congruently one above another, so that overall no lateral distances have to be bridged within the printed circuit board at least with respect to the first and second groups of contact connections. The size of the lateral offset, in each case, two semiconductor components arranged on opposite outer sides of the printed circuit board, then corresponds to the distance between two groups of contact connections on the respective semiconductor component.

It is preferably provided that, within the printed circuit board, the first contact connections of the respective second semiconductor component which is arranged in a lateral direction between two first semiconductor components on the opposite main area of the printed circuit board are short-circuited with the first contact connections of one first semiconductor component and the second contact connections of the relevant second semiconductor component are short-circuited with the second contact connections of the other first semiconductor component. Accordingly, the two groups of contact connections of each second semiconductor component arranged on the rear side of the printed circuit board are connected to in each case one group of contact connections of the two first semiconductor chips arranged on the front side of the printed circuit board, the base area of each of which partly overlaps the relevant second semiconductor component. One of said two first semiconductor components is arranged in offset fashion in such a way that its group of first contact connections are arranged in a direction parallel to the printed circuit board in the same or approximately the same position as the corresponding group of first contact connections of the second semiconductor chip on the rear side of the printed circuit board. The other first semiconductor chip is arranged in offset fashion such that its group of second contact connections are arranged parallel to the printed circuit board in the same position as the corresponding group of second contact connections of the second semiconductor chip on the rear side of the printed circuit board. Consequently, the base areas of the two first semiconductor chips of the quantity of first semiconductor chips which are arranged on the top side of the printed circuit board therefore in each case maximally overlap by half the base areas of the relevant second semiconductor chips which are arranged between them in the lateral direction but on the rear side of the printed circuit board.

It is preferably provided that the printed circuit board has conductor tracks which form a first line bus and a second line bus, the first line bus interconnecting the first contact connections of all the semiconductor components of the plurality of semiconductor components and the second line bus interconnecting the second contact connections of all the semiconductor components of the plurality of semiconductor components. Each line of the first or second line bus therefore makes contact with each of the first and second semiconductor components by virtue of branchings leading to the contact connection thereof. In the case of the lines of the first line bus, said branchings lead to contact connections which are in each case arranged in the group of the first contact connections of the relevant (first or second) semiconductor chip. In the case of the lines of the second line bus, the branchings lead to respective contact connections which belong to the group of the second contact connections and are therefore arranged in the second array of contact connections, which is situated nearer to the relevant second edge of the semiconductor component (than to the first edge).

It is provided that the first line bus comprises contact hole fillings which are arranged within the printed circuit board and with the aid of which contact is made with the groups of first contact connections of the first and second semiconductor components arranged congruently on the mutually opposite main areas of the printed circuit board. The contact hole fillings (vias) lead through dielectric layers between the conductor track planes of the printed circuit board; at least in each case one contact hole filling per first and per second semiconductor component is provided if the conductor track plane in which the first line bus runs is an inner conductor track plane of the printed circuit board. Furthermore, the line branches leading to the individual semiconductor components may, of course, comprise even further conductive structures which, however, only have to bridge small distances parallel to the printed circuit board.

Preferably, it is provided that the second line bus comprises contact hole fillings which are arranged within the printed circuit board and with the aid of which contact is made with the groups of second contact connections of the first and second semiconductor components arranged congruently on the mutually opposite main areas of the printed circuit board. Accordingly, each line of the second line bus as well comprises in each case at least one contact hole filling per first and per second semiconductor component provided that the second line bus is arranged in a central conductor track plane.

It is provided that each second semiconductor component extends in the lateral direction over a distance between two first semiconductor components and overlaps the base area of the two first semiconductor components in regions, the overlap region being smaller than half of the base area of the respective first semiconductor component. The distance between the two first semiconductor components which are arranged directly adjacent to one another on the front side is preferably chosen such that the mutually facing groups of first contact connections of one semiconductor chip and of second contact connections of the other semiconductor chip are arranged on the front side of the printed circuit board at a distance from one another which corresponds to the distance between the group of first contact connections and the group of second contact connections of each semiconductor component. As a result, it is possible to arrange a second semiconductor component with respect to the groups of first and second contact connections congruently on the rear side of the printed circuit board; a group of first contact connections is then arranged congruently (in the same position in the lateral direction), with respect to the group of first contact connections of one of the nearest semiconductor component arranged on the top side. Correspondingly, the contact connections of the second group of the semiconductor component arranged on the rear side are also arranged in the same lateral position as the group of second contact connections of the other nearest semiconductor component arranged on the top side.

It is provided that the second semiconductor components are arranged on the printed circuit board in the same position as the first semiconductor components with respect to the second direction. All of the first and second semiconductor components, are arranged on the front side and on the rear side, of the plurality of semiconductor components which in each case have the same coordinates and also the same orientation with regard to the second direction, parallel to the main areas of the printed circuit board. This last means that in each case the same edge of all the first and second semiconductor components face the same direction, for example the positive second direction. If a corner of each semiconductor component that is situated where the first edge and the aforesaid edge in each case abut were marked with a marking, then said marking would point in the direction of the positive second direction in the case of each first and also second semiconductor chip. All the semiconductor components are thus arranged in the same position with respect to the second direction, but are lined up in a manner offset with respect to one another along the first direction, parallel to which the main areas of the printed circuit board likewise run.

It is preferably provided that the printed circuit board is a multilayer printed circuit board having a plurality of conductor track planes, the first and the second line bus running in at least one inner conductor track plane. The first and the second line bus may run in the same conductor track plane or be distributed over a plurality of inner conductor track planes. Although not necessary, it is nonetheless advantageous if the line buses run in a single inner, central conductor track plane since the line paths in the direction perpendicular to the printed circuit board by means of which the contact connections of the first and second semiconductor components are connected can then be chosen to have an identical length with a lower outlay.

It is preferably provided that the first and the second contact hole fillings of the line buses are arranged in regions of the printed circuit board in which the base area of a first semiconductor component and the base area of a second semiconductor component in each case overlap. The overlap, in this case, is not only the base areas, the lateral dimensions of in a first and a second semiconductor component or a semiconductor component mounted on the front side and a semiconductor component mounted on the rear side on the printed circuit board, but also, in the overlap region, the positions of the respective mutually corresponding groups of contact connections of the semiconductor components. With respect to the groups of first and second contact connections, this lateral overlap is so large that apart from the internal distribution of contact connections within the respective array of contact connections the positions of the relevant array of first or second contact connections on the two main areas of the printed circuit board in the lateral direction are identical. Consequently, it is possible to reduce connecting paths running parallel to the printed circuit board between the branching points and the contact connections of the semiconductor components to the smallest possible amount. This is achieved most simply by means of the contact hole fillings all or for the most part being arranged in the region of the lateral dimension of the printed circuit board in which the arrays of contact connections of in each case a semiconductor component fitted on the top side and a semiconductor component fitted on the underside in each case attain congruence.

It is preferably provided that the first and the second contact hole fillings of the first line bus are arranged in regions of the printed circuit board in which the group of first contact connections of a first semiconductor component is in each case arranged congruently with the group of first contact connections of a second semiconductor component in a lateral direction.

Furthermore, it is preferably provided that the first and the second contact hole fillings of the second line bus are arranged in regions of the printed circuit board in which the group of second contact connections of a first semiconductor component is in each case arranged congruently with the group of second contact connections of a second semiconductor component in a lateral direction. In accordance with these embodiments, the contact hole fillings of the second line bus are in each case situated at different lateral positions of the printed circuit board than the contact hole fillings of the first line bus.

Moreover, along the first direction, the positions in which a respective group of first contacts of a respective upper and lower semiconductor component are arranged in each case alternate with positions in which a respective group of second contact connections of a respective upper and lower semiconductor component are arranged. The spatial separation of contact connections which are driven by the first line bus from those contact connections which are to be driven by the second line bus leads to a disentanglement of the internal interconnection within the printed circuit board and hence to a simplification of the internal printed circuit board construction. The spatial separation of the first and second contact connections of all the semiconductor chips from one another thus enables a particularly simple printed circuit board course which leaves much more leeway for design configurations and other criteria than in the case of a conventional electronic component.

It is preferably provided that the printed circuit board has a contact strip which runs along the first direction at a first edge of the printed circuit board and has a multiplicity of contacts lined up along the first direction. Particularly in the case of a component embodied as a memory module, the contact strip serves for inserting the component into an adapter of a motherboard or some other superordinate electronic unit.

It is preferably provided that the printed circuit board has two second edges which are remote from one another and between which the first edge of the printed circuit board extends. Each of the second edges adjoins the first edge of the printed circuit board, along which the contact strip of the printed circuit board is arranged, at a respective corner of the printed circuit board. The printed circuit board thus extends along the first direction between the two second edges and along the second direction from the first edge as far as a further edge. By way of example, the semiconductor components are lined up in a direction parallel to the contact strip. However, they may equally be lined up in a direction perpendicular to the course of the contact strip in this case, groups of semiconductor components each have different positions along the contact strip, but the semiconductor components of each group have, among one another, the same position along the first direction. In each group, the semiconductor components of the relevant group are then lined up in a direction parallel to the second edges, that is to say perpendicular to the course of the contact strip.

It is preferably provided, however, that the semiconductor components are lined up parallel to the contact strip on opposite main areas of the printed circuit board in a manner offset with respect to one another along the first direction, the line buses extending over a region of the printed circuit board which corresponds to at least eighty percent of the distance between the two second edges of the printed circuit board. As a result, a large part of the width of the printed circuit board can be provided for the arrangement of at least one lining-up of semiconductor chips which overlap in regions in the lateral direction.

It is preferably provided that the device has at least two groups of semiconductor components, the semiconductor components of each group of semiconductor components being arranged in a manner overlapping one another in regions on the two main areas of the printed circuit board and being connected up to one another by a first and a second line bus. Two different groups of semiconductor components are provided in this case, each group having first semiconductor components, mounted on the front side, and second semiconductor components, mounted on the rear side. It goes without saying that the front and rear sides are interchangeable.

It is preferably provided that the line buses of each group of semiconductor components in each case begin in a central region of the printed circuit board between the two second edges of the printed circuit board and end in the vicinity of one of the two second edges of the printed circuit board. This enables a symmetrical arrangement of two or (a number of 2n) groups of semiconductor components with a dedicated first and second line bus. Each group preferably has the same number of semiconductor components.

It is preferably provided that each line bus is connected to a driver circuit. A dedicated driver circuit may be provided for each first and second line bus. The driver circuits may be drivers of a register, by way of example.

It may be provided that each line bus ends at contact connections of a last semiconductor component. If a plurality of groups of semiconductor components are provided each having a dedicated first and second line bus, the respective line bus ends at the last, for example outermost, semiconductor component of the relevant group of semiconductor components.

As an alternative, it may be provided that each line bus ends at terminating resistors. The terminating resistors, which serve to terminate the line buses, prevent electrical signals from being reflected back and therefore have an electrical resistance chosen in a suitable manner.

It is preferably provided that the line buses in each case comprise control lines and address lines. Control signals, for example write commands or read commands, are communicated via the control lines and memory addresses for writing in data, reading out data or refreshing memory cells communicated via the address lines.

It is preferably provided that the semiconductor components are connected up in parallel with one another by the lines of the address bus. This is ensured by the use of fly by technology, in which the lines of the line buses lead through between the semiconductor chips fitted on both sides and make contact with the semiconductor chips arranged along the line course by means of only short line branches.

It is preferably provided that the printed circuit board has separate data lines for each semiconductor component, to which data lines the respective semiconductor component is connected. Consequently, dedicated data lines are provided for each semiconductor component, whereas the control commands and the address commands are communicated by a common data bus (distributed between the first and second line buses), which has in each case only very short branchings to the respective contact connections of the semiconductor components.

It is preferably provided that each first and second semiconductor component which is fitted at the first or second main surface of the printed circuit board in each case carries at least one further semiconductor component. In this development, further semiconductor components can be driven by means of the same printed circuit board. However, they are not fixed directly to the printed circuit board, but rather to one of those semiconductor components which are fixed directly to the printed circuit board.

It is preferably provided that the semiconductor components are packaged semiconductor chips. The packages may be ball grid arrays (BGA), by way of example. Furthermore, it is preferably provided that the semiconductor components in each case have an integrated semiconductor memory. The integrated semiconductor memories may be, in particular, volatile read/write memories, for example DRAMs (Dynamic Random Access Memories).

It is preferably provided that the semiconductor components have a non-square plan, in which case they have a larger and a smaller lateral dimension, and in which case the first and the second edge of the semiconductor components in each case predefine the larger dimension and the distance between the first and the second edge corresponds to the smaller dimension. The smaller dimension corresponds for example to the length of that edge which, pointing in the positive second direction, runs between the first and the second edge of the respective semiconductor component.

It is preferably provided that the electronic device is a memory module. However, it may equally be provided that the electronic device is a memory unit of a mobile device, for example of a mobile phone.

The invention is furthermore achieved by means of a method for producing an electronic device, the method having the following steps:

a) provision of a printed circuit board having a first main surface and a second main surface remote from the first main surface, the main surfaces extending along a first and a second direction and semiconductor components being mountable thereon, and provision of a plurality of semiconductor components of mutually identical type,
each semiconductor component having an outer surface extending from a first edge of the semiconductor component as far as an opposite second edge of the semiconductor component, and contact connections which are provided in the region of the outer surface and are arranged in two groups of contact connections on the outer surface,
a group of first contact connections in each case being arranged in a region of the outer surface of the semiconductor component which is arranged nearer to the first edge of the semiconductor component, and a group of second contact connections in each case being arranged in a region of the outer surface of the semiconductor component which is arranged nearer to the second edge of the semiconductor component, and

b) mounting of the semiconductor components on the printed circuit board, first semiconductor components of the plurality of semiconductor components being mounted on the first main surface and second semiconductor components of the plurality of semiconductor components being mounted on the second main surface of the printed circuit board in such a way
that the first and the second edge of all the semiconductor components run parallel to the second direction, and that the first edge of the second semiconductor components points in the opposite direction to the first edge of the first semiconductor components, and
that, with regard to the first direction in a position between in each case two first semiconductor components which are arranged adjacent to one another on the first main surface of the printed circuit board, a second semiconductor component is in each case arranged on the second main surface of the printed circuit board, the base area of said semiconductor component on the printed circuit board in each case overlapping the base areas of the respective first semiconductor components in regions along the first direction, and
that, in a lateral direction, in each case the group of first contact connections of the second semiconductor component attains congruence with the group of first contact connections of one of the two first semiconductor components and the group of the second contact connections of the second semiconductor component attains congruence with the group of second contact connections of the other of the two first semiconductor components.

In particular, it is provided that an electronic device as claimed in one of claims 1 to 31 is produced with the aid of this method.

### BRIEF DESCRIPTION OF THE DRAWINGS

The invention is described below with reference to the figures, in which:

FIG. 1 shows a schematic plan view of an electronic device according to the invention;

FIG. 2 shows a perspective schematic view of a semiconductor component;

FIG. 3 shows a schematic partial cross-sectional view of the electronic device according to the invention from FIG. 1;

FIG. 4 shows a detailed view with respect to FIG. 3;

FIG. 5 shows an embodiment of the electronic device according to the invention; and

FIG. 6 shows a further embodiment of the electronic device according to the invention.

### DETAILED DESCRIPTION OF ILLUSTRATIVE EMBODIMENTS

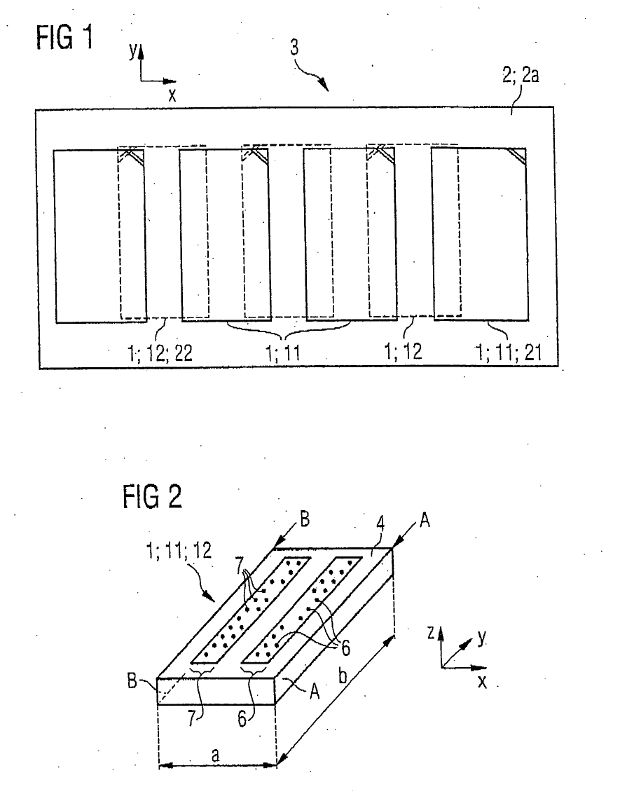

FIG. 1 shows a schematic plan view of an electronic device 3 according to the invention, which has an electronic printed circuit board 2 illustrated in the plan view of its main area 2a in FIG. 1. The electronic device 3 may be a memory module, but equally a memory unit of a mobile device such as a mobile phone, for example. However, the electronic device may equally be any other electronic unit having a printed circuit board populated with semiconductor components 1 on both sides.

Semiconductor components 1, namely first semiconductor components 11, are arranged on the first main surface 2a of the printed circuit board 2 that is illustrated in FIG. 1. Further semiconductor components 1, namely second semiconductor components 12, which are illustrated by dashed lines in FIG. 1, are arranged on the second main surface of the printed circuit board 2. The semiconductor components 1 are arranged on the printed circuit board 2 such that they are lined up with respect to a first direction x along which the main areas of the printed circuit board 2 extend, and are arranged in the same position in each case along a second direction y along which the main areas likewise extend. As can be discerned in FIG. 1, the base areas 21 of the first semiconductor components 11 arranged on the first main surface 2a overlap the base areas 22 of the second semiconductor components 12 arranged on the opposite main area of the printed circuit board 2. In particular, the semiconductor components are arranged such that the base area of a respective second semiconductor component 12 partly overlaps the base area of at least one first semiconductor component 11. The arrangement according to the invention of semiconductor components as illustrated in FIG. 1 enables a simpler interconnection of semiconductor components which in each case have two groups of contact connections, as illustrated in FIG. 2, and additionally enables the electronic device to be operated at higher clock frequencies than conventional electronic devices, for example above 800 megahertz.

In FIG. 1, a corner of each first semiconductor component 11 and second semiconductor component 12 is marked with a marking that identifies the orientation of the relevant semiconductor component. In FIG. 1, said marking is situated at the top right corner in the case of the first semiconductor components 11 arranged on the first main surface 2a, and at the corner illustrated top left in FIG. 1 in the case of the second semiconductor components arranged on the opposite main area in the manner illustrated by dashed lines. This illustrates how the first semiconductor components 11 and the second semiconductor components 12 are arranged in a manner oriented with respect to one another on the printed circuit board. All the semiconductor components 1 are structurally identical among one another. In particular, the first semiconductor components 11 are structurally identical to the second semiconductor components 12.

FIG. 2 shows a schematic perspective view of a semiconductor component 1 which is arranged in corresponding numbers on the two main areas of the printed circuit board, with the highest possible packaging density on the smallest possible printed circuit board area. The semiconductor component 1 is for example a packaged semiconductor chip and thus has an integrated semiconductor circuit. The semiconductor component is in particular a ball grid array (BGA) or some other component. In any event it has two arrays or groups of contact connections, namely a group of first contact connections 6 and a group of second contact connections 7. Both groups of contact connections are arranged in an outer surface 4 by which the semiconductor component 1 is to be mounted at the printed circuit board.

The semiconductor component 1 has a plan or a base area having preferably a non-square cross section, the smaller lateral dimension being identified by a, for example, and the larger lateral dimension being identified by b, for example. Along one of the two dimensions, for example along the dimension a, the semiconductor component 1 extends from a first edge A as far as an opposite second edge B. The outer surface 4 extends in between. The group of first contact connections 6 is arranged in a first region of the outer surface 4, the group of first contact connections 6 being arranged nearer to the first edge A than to the second edge B. Conversely, the group of second contact connections 7 is arranged nearer to the second edge B than to the first edge A. The semiconductor component illustrated in FIG. 2 is arranged in the corresponding numbers on the printed circuit board 2 illustrated in FIG. 1 and is mounted at said printed circuit board, the arrangement, offset laterally along the first direction x, of such semiconductor components which are mounted on opposite main areas of the printed circuit board enabling a simplified electrical driving of the semiconductor components by the printed circuit board.

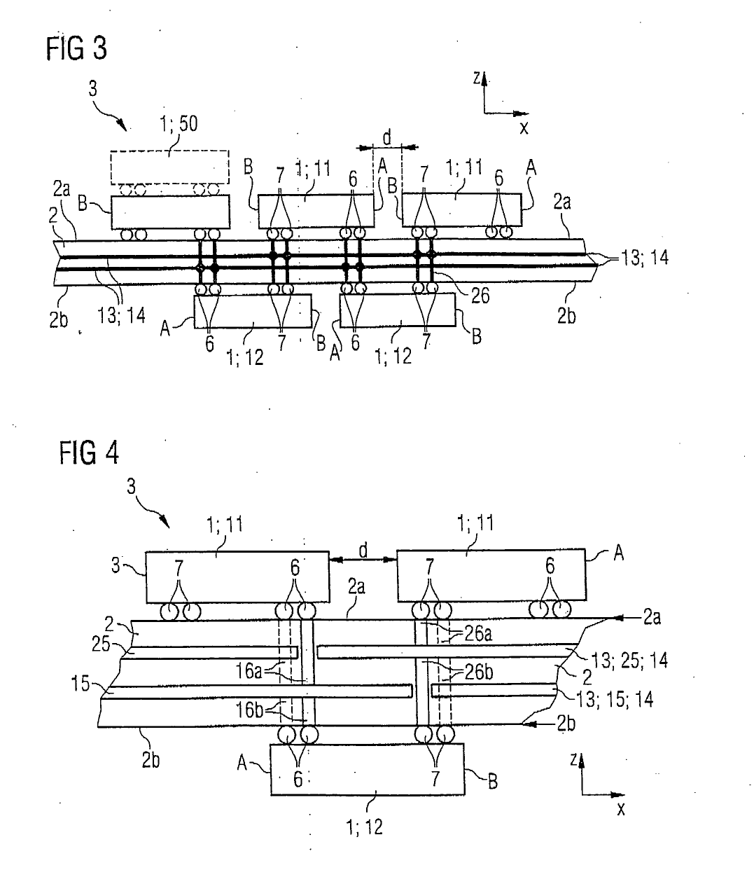

FIG. 3 shows a schematic cross-sectional view of the electronic device from FIG. 1. The illustration shows the cross-sectional view along the first direction x parallel to the printed circuit board and in the direction z perpendicular thereto. In the sectional view, each of the first 11 and second semiconductor components 12 extends in each case between its first edge A and its second edge B. In the case of the first semiconductor components 11 arranged on the first main surface 2a of the printed circuit board 2, the first edge A points in the positive first direction x in FIG. 3, whereas in the case of the semiconductor components 12 arranged on the second main surface 2b, their first edge A points in the negative x direction. By contrast, the second edge B of the second semiconductor components 12 points in the positive x direction. Consequently, the first edge A of the second semiconductor components 12 points in the opposite direction to the first edge A of the first semiconductor components 11. There is no difference between the first 11 and second semiconductor components 12; they are structurally identical among one another, but merely arranged on different main areas 2a and 2b of the printed circuit board. Each of the semiconductor components 11 and 12 may additionally carry one or more further semiconductor components 50, as indicated using the example of the first semiconductor component 11 illustrated on the left in FIG. 3. This will not be discussed any further hereinafter, in order that the further figures are rendered with clarity.

In each case two first semiconductor components 11 are arranged adjacent to one another on the first main surface 2a, to be precise at a distance d. The said distance d is coordinated with the offsetting according to the invention of the second semiconductor components 12 arranged on the second main surface 2b, to be precise in such a way that the distance between the group of first contact connections 6 of one of the two first semiconductor components 11 and the group of second contact connections 7 of the adjacent first semiconductor component 11 precisely corresponds to the distance between the two groups of contact connections 6 and 7 on an individual semiconductor component 12. This makes it possible for the second semiconductor components 12 to be arranged on the second main surface 2b of the printed circuit board in each case in a manner offset with respect to the first semiconductor components 11 such that the contact connections 6 and 7 of each second semiconductor component 12 attain congruence with those contact connections 6 and 7 of the first semiconductor components 11 between whose base areas the respective second semiconductor component 12 is arranged. This means that the group of first contact connections 6 of each lower semiconductor component 12 has the same position in the lateral direction x as the group of first contact connections 6 of one upper semiconductor component 11 whose base area is overlapped by the base area of the second semiconductor component 12. This furthermore means that the position of the group of second contact connections 7 of the lower semiconductor component 12 is the same as the position of the second contact connections 7 of a further upper semiconductor component 11 whose base area is overlapped by the base area of the lower semiconductor component 12.

The arrangement according to the invention of semiconductor components on the printed circuit board has the advantage that the semiconductor components 11 and 12 can be operated by a fly by bus, which leads through between them, with the shortest possible branching lines. In this respect, FIG. 3 schematically illustrates a first and a second conductor track plane 13; in each case a multiplicity of conductor tracks 14 run in both conductor track planes 13. The conductor tracks 14 thus lead through between the front-side 11 and rear-side semiconductor components 12 in one or more central conductor track planes of the printed circuit board 2. Schematically illustrated branching nodes indicate the sections of the lines 14 from which contact hole fillings or vias in each case lead to the contact connections 6 and 7 of the respective semiconductor components 1. It can be discerned in FIG. 3 that, from the conductor tracks 14 of a lower conductor track plane 3, contact hole fillings lead to the first contact connections 6 both of the front-side semiconductor components 11 and of the rear-side semiconductor components 12. From the conductor tracks 14 of a further inner conductor track plane 13, by contrast, there proceed contact hole fillings or other line paths formed from a plurality of conductive structures, which lead to the second contact connections 7 of the first semiconductor components 11 and of the second semiconductor components 12. Consequently, the lines of a first line bus, for example, which is arranged in the lower conductor track plane 13, for example, serve exclusively for first contact connections of all the semiconductor components, whereas the conductor tracks of the other conductor track plane illustrated at the top, for example, in FIG. 3 make contact exclusively with the second contact connections 7 of all the semiconductor components 11 and 12. Since the second contact connections 7 are in each case arranged in a separate contact array in the vicinity of the respective edge B (c.f. FIG. 2), that is to say in a manner spatially separated from the contact array for the group of first contact connections 6 of each semiconductor component, the arrangement illustrated in FIG. 3 has the advantage that, on the top side and the underside of the printed circuit board 2, in each case the first contact connections lie one above another and likewise the second contact connections lie one above another. Therefore, only comparatively short conductor track paths parallel to the printed circuit board area are necessary in order for example to make contact with the first contact connections 6 of all the first and second semiconductor components 11 and 12. This would be different if, as in conventional electronic devices, the front-side and rear-side semiconductor components were arranged without an offset, that is to say at in each case the same positions within the printed circuit board area, or if the first edges A of the rear-side semiconductor components B likewise pointed in the positive x direction, contrary to the illustration in FIG. 3.

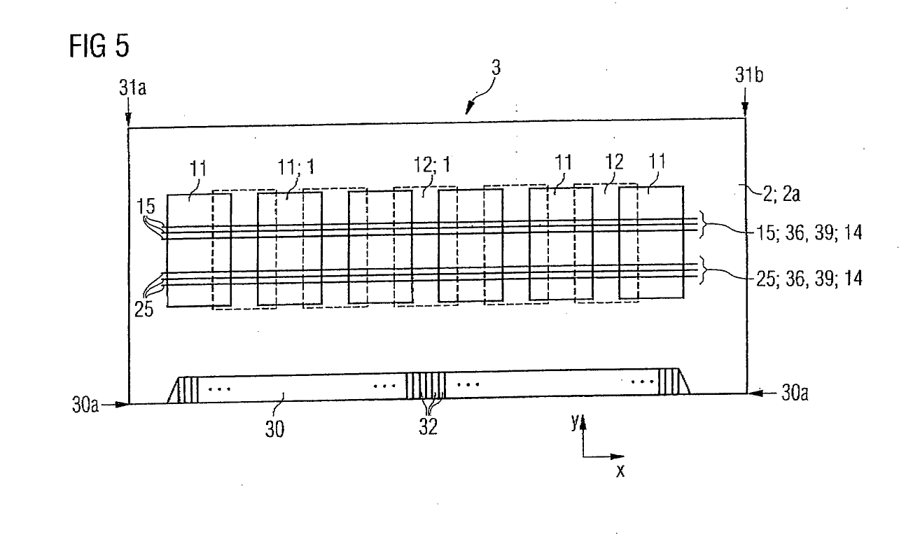

FIG. 3 and likewise FIG. 4 described below illustrate the conductor tracks 14 of a plurality of line buses in each case in different conductor track planes 13, in order that the illustration is rendered with greater clarity. It must be emphasized, however, that in practice both the line bus for driving all the first contact connections 6 and the line bus for driving all the second contact connections 7 can be situated in the same common conductor track plane 13.

FIG. 4 shows an enlarged detail view with respect to FIG. 3. In particular, the inner construction of the printed circuit board 2 is illustrated in greater detail in FIG. 4. The illustration once again shows the cross section along the first lateral direction x along which the two main areas 2a and 2b of the printed circuit board 2 extend, and along the direction z of the normal. In particular, two conductor track planes 13 are illustrated, in which conductor tracks 14 run, only a single conductor track 14 of which in each case can be discerned in the sectional view of FIG. 4. However, each conductor track 14 from FIG. 4 in each case corresponds to a multiplicity of conductor tracks.

FIG. 4 illustrates that a first line bus 15 runs in one inner conductor track plane 13, the said first line bus serving for making contact with the respective group of first contact connections 6 of each first 11 and second semiconductor component 12. For this purpose, the first line bus 15 comprises, with respect to each conductor track 14 running in the at least one inner conductor track plane 13, first contact hole fillings 16a leading to the first contact connections 6 of the semiconductor components 11 arranged on the first main surface 2a, and also second contact hole fillings 16b leading to the first contact connections 6 of the semiconductor components 12 arranged on the second main surface 2b. The plurality of semiconductor components 11 and 12 are additionally connected to the first line bus 15 and also to the second line bus 25, the conductor tracks 14 of which are illustrated in a further conductor track plane 13 in FIG. 4 for the sake of clearer illustration. However, the lines of the second line bus 25 are preferably formed in the same conductor track plane 13 as the lines of the first line bus 15. It can be discerned in FIG. 4 that first contact hole fillings 26a proceed from the lines of the second line bus 25 and lead to the second contact connections 7 of the semiconductor components 11 arranged on the first main surface 2a. Furthermore, the second line bus 25 comprises second contact hole fillings 26a leading to the second contact connections 7 of the semiconductor components 12 arranged on the second main surface 2b. In the region of the second contact hole fillings 26b of the second line bus 25, the conductor track 14 of the first line bus 15 that is illustrated in FIG. 4 is illustrated as interrupted; it leads around the contact hole filling 26b in the lateral direction or is arranged in the same conductor track plane as the second line bus 25, so that the contact hole filling 26b and the conductor track 14 of the first line bus 15 are not in the way. It can be discerned on the basis of the line course in FIG. 4 that, proceeding from the first line bus 15, that is to say from the inner conductor track plane 13 illustrated at the bottom in FIG. 4, the first contact connections 6 of all the semiconductor components 1, to be precise both of the front-side semiconductor components 11 and of the rear-side semiconductor components 12, are driven and are conductively connected to one another. Likewise, by means of the conductor tracks 14 of the second line bus 25, which is illustrated at a different level in FIG. 4 for the sake of clarity, contact is made with all the second contact connections 7 of the semiconductor components 11, to be precise likewise both of the front-side semiconductor components 11 and of the rear-side semiconductor components 12. In contrast to conventional electronic devices, the respectively mutually corresponding groups of contact connections, for example, of first contact connections 6 of the semiconductor components arranged on the front side and on the rear side of the printed circuit board, attain congruence, so that the line branches to the individual semiconductor components 11 and 12, which line branches are schematically illustrated in a simplified manner by the contact hole fillings 16a, 16b, 26a, 26b in FIG. 4, can be chosen to be significantly shorter than in the case of conventional electronic devices because longer lateral path distances of the branching lines parallel to the printed circuit board area are largely obviated. Slight lateral offsets are also necessary at most within the region of the printed circuit board area within which the respective contact array for the group of first and second contact connections 6 and 7 extends, in order in each case to short-circuit the correct individual first and second contact connections with one another. However, the necessity of using the branching lines to bridge lateral distances corresponding approximately to the distance between the group of first contact connections 6 and the group of second contact connections 7 of a semiconductor component is obviated. On account of the shortened signal paths, the electronic device according to the invention can be operated at considerably higher frequencies than conventional devices equipped with semiconductor components which assume the same lateral positions in each case on the front side and the rear side of the printed circuit board. The electronic device according to the invention can be operated reliably in particular at frequencies above 800 megahertz.

FIG. 5 shows a schematic plan view of a further embodiment of the electronic device according to the invention. In this case, the electronic device 3 is formed as a memory module, for example, and has a contact strip 30 on the printed circuit board 2, said contact strip running along a first edge 30a and having a multiplicity of contacts 32 along the first direction x. The contact strip 30 comprising the contacts 32 is formed on both main areas of the printed circuit board 2. The printed circuit board may be able to be plugged in particular into a motherboard or into some other superordinate electronic unit. The printed circuit board 2 has two mutually opposite second edges 31a and 31b between which the printed circuit board 2 and the first edge 30a thereof extend. FIG. 5 illustrates an exemplary embodiment in which, in direction x, the first 11 and second semiconductor components 12 arranged offset with respect to one another extend over more than 80 percent of the distance between the two second edges 31a and 31b. The semiconductor components 11 and 12 arranged offset with respect to one another are driven by a first line bus 15 and by a second line bus 25 each having a plurality of conductor tracks 14. They are supplied in particular with control commands and address commands by means of said line buses. Accordingly, both the first line bus 15 and the second line bus 25 in each case contain a plurality of control lines 36 and a plurality of address lines 39.

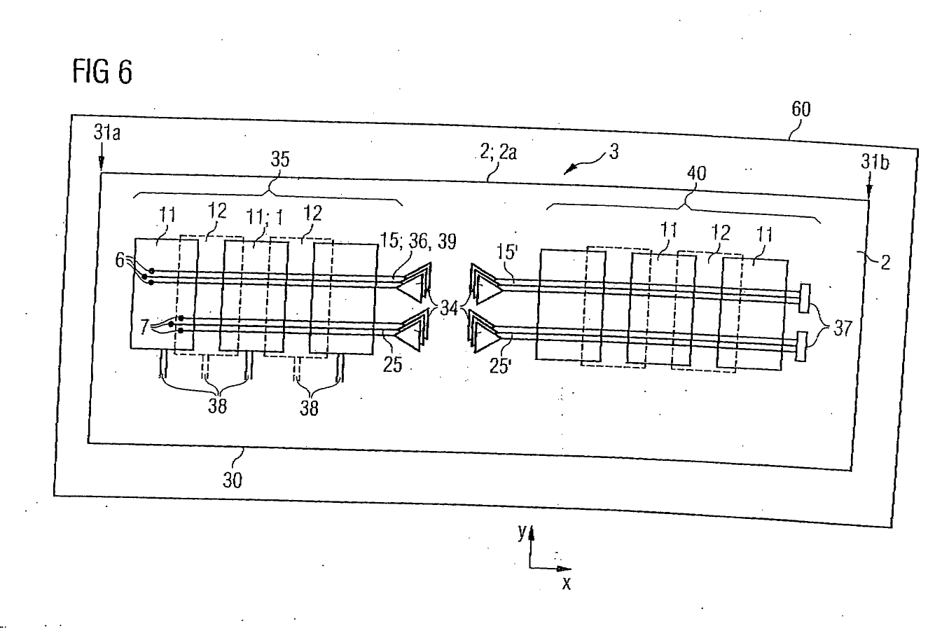

FIG. 6 shows a further exemplary embodiment, in which two groups 35 and 40 of semiconductor components 11 and 12 arranged offset with respect to one another are arranged on the printed circuit board 2. Each group 35 and 40 of semiconductor components in each case has dedicated line buses. Thus, the semiconductor components 11 and 12 of the first group 35 of semiconductor components are connected by a first line bus 15 and a second line bus 25. Furthermore, as illustrated only for the first group 35 of semiconductor components, separate data lines 38 are provided for each individual semiconductor component 11 and 12, to which data lines the respective semiconductor component is connected in order to receive the data to be read in. The control lines 36 and address lines 39 of the line buses 15 and 25 may proceed approximately from the center of the printed circuit board 2 between the two second edges 31a and 31b and be connected to driver circuits 34, for example. The driver circuits 34 may be for example driver circuits of a register. The opposite ends of the lines of the line buses may either, as illustrated for the case of the group 35 of semiconductor components, end at contact connections 6 and 7 of a last semiconductor component 11, which, in FIG. 6, is arranged in the region of the second edge 31a of the printed circuit board 2 that is illustrated on the left. As an alternative, as is illustrated on the basis of the second group 40 of semiconductor components, the lines of the line buses 15′ and 25′ may, however, likewise end at terminating resistors 37 after they have previously made contact with all the semiconductor components of the second group 40. The terminating resistors serve to terminate the line buses and prevent reflected signals from arising. The groups 35 and 40 of semiconductor components show two different embodiments, each of which can be realized in the same way for both groups in the case of a concrete memory module or a concrete electronic device. Consequently, FIG. 6 illustrates two different embodiments in the left-hand and right-hand halves. The data lines are illustrated by way of example only for the semiconductor components of the first group 35 in FIG. 6. The device 3 in accordance with FIG. 6 may be part of a mobile device 60, for example of a mobile phone, but may equally also be integrated in some other superordinate electronic unit, for example a motherboard or a mainframe. In this case, said superordinate electronic unit corresponds to the reference symbol 60. Furthermore, in FIGS. 5 and 6 the respective embodiments are interchangeable in particular to the extent that two or more different groups of semiconductor components which are connected up to one another by respectively dedicated line buses may likewise be provided in FIG. 5 as well. A different number of groups of semiconductor components which in each case have a dedicated first and second line bus may likewise be provided in FIG. 6.

The arrangement according to the invention of semiconductor components on a printed circuit board enables the electronic device to be operated reliably in particular at clock frequencies above 800 megahertz; relatively long line branches which, in conventional memory modules, run over relatively long distances parallel to the printed circuit board area proceeding from a branching node are obviated on account of the spatial proximity in each case of the first contact connections of the semiconductor chips with respect to one another and of the second contact connections of the semiconductor components with respect to one another.

1-32. (canceled)

33. An electronic device comprising at least one printed circuit board and comprising a plurality of semiconductor components of mutually identical type:
the printed circuit board having a first main area and a second main area remote from the first main area, which extend along a first and a second direction;
the plurality of semiconductor components comprising first semiconductor components arranged on the first main area of the printed circuit board, and second semiconductor components arranged on the second main area of the printed circuit board;
each semiconductor component having an outer area that faces the printed circuit board and extends from a first edge of the semiconductor component as far as an opposite second edge of the semiconductor component;
each semiconductor component having contact connections that are provided in the region of its outer area and are arranged in two groups of contact connections on the outer area;
a group of first contact connections in each case being arranged in a region of the outer area of the respective semiconductor component which is arranged nearer to the first edge of the semiconductor component, and a group of second contact connections in each case being arranged in a region of the outer area of the respective semiconductor component which is arranged nearer to the second edge of the semiconductor component;
the semiconductor components being arranged in oriented fashion on the printed circuit board such that the first and the second edge of the semiconductor components run parallel to the second direction, and that the first edge of the second semiconductor components points in the opposite direction to the first edge of the first semiconductor components;
the semiconductor components of the plurality of semiconductor components being lined up in a manner offset with respect to one another along the first direction such that, with respect to the first direction in a position between in each case two first semiconductor components that are arranged adjacent to one another on the first main area of the printed circuit board, a second semiconductor component is in each case arranged on the second main area of the printed circuit board, the base area of said semiconductor component on the printed circuit board in each case overlapping the base areas of the respective first semiconductor components on the printed circuit board in regions along the first direction; and
in a direction parallel to the main areas of the printed circuit board, in each case the group of the first contact connections of the second semiconductor component attaining congruence with the group of the first contact connections of one first semiconductor component and the group of the second contact connections of the second semiconductor component attaining congruence with the group of the second contact connections of the other first semiconductor component.

34. The device as claimed in claim 33, wherein, within the printed circuit board, the first contact connections of in each case one second semiconductor component that is arranged centrally between two first semiconductor components on the opposite main area of the printed circuit board are short-circuited with the first contact connections of one of said two first semiconductor components and the second contact connections of the same second semiconductor component area short-circuited with the second contact connections of the other of the two first semiconductor components.

35. The device as claimed in claim 33, wherein the printed circuit board includes conductor tracks that form a first line bus and a second line bus, the first line bus interconnecting the first contact connections of all the semiconductor components of the plurality of semiconductor components and the second line bus interconnecting the second contact connections of all the semiconductor components of the plurality of semiconductor components.

36. The device as claimed in claim 35, wherein, within the printed circuit board, the first line bus comprises contact hole fillings that make contact with the first contacts of the semiconductor components mounted on both sides, and the second line bus comprises contact hole fillings that make contact with the second contacts of the semiconductor components mounted on both sides.

37. The device as claimed in claim 36, wherein the first and the second line bus in each case comprise first contact hole fillings and second contact hole fillings, the first contact hole fillings leading to the first semiconductor components and the second contact hole fillings leading to the second semiconductor components.

38. The device as claimed in claim 37, wherein the first and the second contact hole fillings of the line buses area arranged in regions of the printed circuit board in which the base area of a first semiconductor component and the base area of a second semiconductor component in each case overlap.

39. The device as claimed in claim 37, wherein the first and the second contact hole fillings of the first line bus are arranged in regions of the printed circuit board in which the group of first contact connections of a first semiconductor component is in each case arranged congruently with the group of first contact connections of a second semiconductor component in a lateral direction.

40. The device as claimed in claim 33, wherein the semiconductor components are lined up parallel to a contact strip of the printed circuit board on opposite main areas of the printed circuit board in a manner offset with respect to one another along the first direction, the line buses extending over a region of the printed circuit board which corresponds to at least eighty percent of the distance between the two second edges of the printed circuit board.

41. The device as claimed in claim 33, wherein the device has at least two groups of semiconductor components, the semiconductor components of each group of semiconductor components in each case being arranged in a manner overlapping one another in regions on the two main areas of the printed circuit board and being connected up to one another by in each case a first and a second line bus.

42. The device as claimed in claim 41, wherein the line buses of each group of semiconductor components in each case begin in a central region of the printed circuit board between the two second edges and end in the vicinity of in each case one of the two second edges of the printed circuit board.

43. The device as claimed in claim 41, wherein each line bus is connected to a separate driver circuit.

44. The device as claimed in claim 41, wherein each line bus ends at contact connections of a last semiconductor component.

45. The device as claimed in claim 41, wherein each line bus ends at terminating resistors.

46. The device as claimed in claim 41, wherein the line buses in each case comprise control lines and address lines.

47. The device as claimed in claim 41, wherein the semiconductor components are connected up in parallel with one another by the conductor tracks of the lines buses.

48. The device as claimed in claim 47, wherein the semiconductor components in each case have at least one volatile read/write memory.

49. The device as claimed in claim 33, wherein the semiconductor components have a non-square base area having a larger and a smaller lateral dimension, the first and the second edge of the semiconductor components in each case predefining the larger dimension and the distance between the first and the second edge corresponding to the smaller dimension.

50. The device as claimed in claim 33, wherein all the semiconductor components are structurally identical to each other, the first contact connections of all the semiconductor components corresponding to one another and the second contact connections of all the semiconductor components corresponding to one another.

51. The device as claimed in claim 33, wherein the electronic device is a memory module or a memory unit of a mobile device.

52. An electronic device comprising:
a printed circuit board comprising a first main area, an opposite second main area and a contact strip; and
a plurality of semiconductor components of mutually identical type, comprising first semiconductor components arranged on the first main area, and second semiconductor components arranged on the second main area;
each semiconductor component having an outer area that faces the printed circuit board and extends between a first edge and an opposite second edge of the semiconductor component;
each semiconductor component on the outer area having a group of first contact connections arranged nearer to the first edge of the semiconductor component, and a group of second contact connections arranged nearer to the second edge of the semiconductor component;
the semiconductor components being arranged in a manner oriented with the first and the second edge perpendicular to the contact strip of the printed circuit board;
the semiconductor components of the plurality of semiconductor components being lined up in a manner offset with respect to one another parallel to the contact strip such that, between in each case two mutually adjacent first semiconductor components, a second semiconductor component is in each case arranged on the second main area of the printed circuit board, the base area of said second semiconductor component on the printed circuit board in each case overlapping the base areas of the respective first semiconductor components on the printed circuit board in regions along the first direction.

53. The device as claimed in claim 52, wherein, on opposite main areas of the printed circuit board, the first contact connections of the second semiconductor component attain congruence with the first contact connections of one first semiconductor component and the second contact connections of the second semiconductor component attain congruence with the second contact connections of the other first semiconductor component.

54. The device as claimed in claim 52, wherein, within the printed circuit board, the first line bus comprises contact hole fillings that make contact with the first contacts of the semiconductor components mounted on both sides, and the second line bus comprises second contact hole fillings that make contact with the second contacts of the semiconductor components mounted on both sides.

55. The device as claimed in claim 52, wherein the first and the second line bus comprise first contact hole fillings and second contact hole fillings, the first contact hole fillings leading to the first semiconductor components and the second contact hole fillings leading to the second semiconductor components.

56. The device as claimed in claim 52, wherein the printed circuit board has conductor tracks that form a first line bus and a second line bus, the first line bus interconnecting the first contact connections of all the semiconductor components of the plurality of semiconductor components and the second line bus interconnecting the second contact connections of all the semiconductor components of the plurality of semiconductor components.

57. The device as claimed in claim 52, wherein the semiconductor components have a non-square base area having a larger and a smaller lateral dimension, the first and the second edge of the semiconductor components in each case predefining the larger dimension and the distance between the first and the second edge corresponding to the smaller dimension.

58. An electronic device comprising:
a printed circuit board comprising a first main area and a second main area, a contact strip, and comprising conductor tracks which form a first line bus and a second line bus;
a plurality of semiconductor components of mutually identical type, comprising first semiconductor components arranged on the first main area, and second semiconductor components arranged on the second main area;
each semiconductor component having an outer area that faces the printed circuit board and extends between a first edge and an opposite second edge of the semiconductor component;
each semiconductor component on the outer area in each case having a group of first contact connections arranged nearer to the first edge of the semiconductor component, and a group of second contact connections arranged nearer to the second edge of the semiconductor component;
the first line bus interconnecting the first contact connections of all the semiconductor components of the plurality of semiconductor components and the second line bus interconnecting the second contact connections of all the semiconductor components of the plurality of semiconductor components; and
a group of first contact connections of a first semiconductor component being arranged congruently with a group of first contact connections of a second semiconductor component arranged in offset fashion and in each case a group of second contact connections of a first semiconductor component being arranged congruently with a group of second contact connections of a second semiconductor component arranged in offset fashion.

59. The device as claimed in claim 58, wherein each line bus is connected to a separate driver circuit.

60. The device as claimed in claim 58, wherein each line bus ends at contact connections of a last semiconductor component.

61. The device as claimed in claim 58, wherein each line bus ends at terminating resistors.

62. The device as claimed in claim 58, wherein the semiconductor components are connected up in parallel with one another by the conductor tracks of the line buses.

63. A method for producing an electronic device, the method comprising:
providing a printed circuit board having a first main area and a second main area remote from the first main area, the main areas extending along a first and a second direction and semiconductor components being mountable on the main areas, and provision of a plurality of semiconductor components of mutually identical type;
each semiconductor component having an outer area extending from a first edge of the semiconductor component as far as an opposite second edge of the semiconductor component, and also contact connections which are provided in the region of the outer area and are arranged in two groups of contact connections on the outer area;
a group of first contact connections in each case being arranged in a region of the outer area of the semiconductor component which is arranged nearer to the first edge of the semiconductor component, and a group of second contact connections in each case being arranged in a region of the outer area of the semiconductor component which is arranged nearer to the second edge of the semiconductor component; and
mounting of the semiconductor components on the printed circuit board, first semiconductor components of the plurality of semiconductor components being mounted on the first main area and second semiconductor components of the plurality of semiconductor components being mounted on the second main area of the printed circuit board in such a way;
wherein the first and the second edge of all the semiconductor components run parallel to the second direction, and wherein the first edge of the second semiconductor components points in the opposite direction to the first edge of the first semiconductor components;
wherein, along the first direction in a position between in each case two first semiconductor components that area arranged adjacent to one another on the first main area of the printed circuit board, a second semiconductor component is in each case arranged on the second main area of the printed circuit board, the base area of said semiconductor component on the printed circuit board in each case overlapping the base areas of the respective first semiconductor components on the printed circuit board in regions along the first direction; and
wherein, along the first direction, in each case the group of first contact connections of the second semiconductor component attains congruence with the group of first contact connections of one of the two first semiconductor components and the group of the second contact connections of the second semiconductor component attains congruence with the group of second contact connections of the other of the two first semiconductor components.

64. An electronic device comprising a printed circuit board having a first main area and an opposite second main area, and comprising a plurality of semiconductor components of mutually identical type, comprising first semiconductor components arranged on the first main area of the printed circuit board, and second semiconductor components arranged on the second main area of the printed circuit board;
each semiconductor component having an outer area running between a first edge and an opposite second edge of the semiconductor component and having a group of first contact connections in a first region of the outer area and a group of second contact connections in a second region of the outer area;
the semiconductor components being arranged in oriented fashion on the printed circuit board such that the first edge of the second semiconductor components points in the opposite direction to the first edge of the first semiconductor components;
the semiconductor components being lined up in a manner offset with respect to one another along the first direction such that, between in each case two first semiconductor components, a second semiconductor component is in each case arranged on the second main area, the base area of said second semiconductor component in each case overlapping the base areas of the respective first semiconductor components in regions; and
in each case the group of the first contact connections of the second semiconductor component attaining congruence with the group of the first contact connections of one of the two first semiconductor components and the group of the second contact connections of the second semiconductor component attaining congruence with the group of the second contact connections of the other of the two first semiconductor components.

65. The electronic device as claimed in claim 64, wherein in each case the first region of the outer area of a respective second semiconductor component attains congruence with the first region of the outer area of one respective first semiconductor component and in each case the second region of the outer area of a respective second semiconductor component attains congruence with the second region of the outer area of a respective other first semiconductor component.
